(19) United States
(12) Patent Application Publication
(10) Pub. No.: US 2023/0395421 A1
(43) Pub. Date: Dec. 7, 2023

(54) MOUNTING PAD, MOUNTING MECHANISM, AND SUBSTRATE TRANSFER MECHANISM

(71) Applicant: Tokyo Electron Limited, Tokyo (JP)

(72) Inventors: Masato OBARA, Miyagi (JP); Gakuto TAKADA, Miyagi (JP); Hideyuki OSADA, Miyagi (JP); Genichi NANASAKI, Miyagi (JP); Kento TOKAIRIN, Miyagi (JP); Shuhei MATSUMOTO, Miyagi (JP)

(73) Assignee: Tokyo Electron Limited, Tokyo (JP)

(21) Appl. No.: 18/206,106

(22) Filed: Jun. 6, 2023

(30) Foreign Application Priority Data
Jun. 6, 2022 (JP) 2022-091651
Apr. 25, 2023 (JP) 2023-071398

(51) Int. Cl. H01L 21/687

(52) U.S. Cl. CPC H01L 21/68735; H01L 21/68707

(57) ABSTRACT

There is a mounting pad for placing an object, comprising: a base; and an annular outer edge portion that is provided on one surface of the base, projects in a direction intersecting a surface direction of said one surface to surround an outer edge of said one surface, and is to be in contact with the object, wherein a thickness of the outer edge portion in at least one portion of the outer edge portion is different from a thickness of the outer edge portion in the other portions of outer edge portion.

### CROSS-REFERENCE TO RELATED APPLICATIONS

This application claims priority to Japanese Patent Application Nos. 2022-091651, filed on Jun. 6, 2022, and 2023-071398, filed on Apr. 25, 2023, respectively, the entire contents of which are incorporated herein by reference.

### TECHNICAL FIELD

The present disclosure relates to a mounting pad, a mounting mechanism, and a substrate transfer mechanism.

### BACKGROUND

There is known a substrate processing apparatus including a plurality of substrate processing chambers for performing substrate processing such as film formation, etching, or the like on a substrate (hereinafter, also referred to as wafer) in a vacuum atmosphere. In this substrate processing apparatus, a substrate is transferred from a container accommodating a plurality of substrates in the atmosphere to a load-lock module by a substrate transfer mechanism of an atmospheric transfer chamber maintained in an atmospheric pressure atmosphere inner atmosphere of the load-lock module can be switched between a vacuum state and an atmospheric pressure, and the substrate is transferred between the atmospheric transfer chamber and a vacuum transfer chamber. The substrate is transferred to each substrate processing chamber by a substrate transfer mechanism of the vacuum transfer chamber maintained in a vacuum atmosphere.

The substrate transfer mechanism in the atmosphere transfer chamber holds the substrate by using a mounting mechanism disposed at the tip end of a transfer arm, for example. The mounting mechanism is provided with a vacuum suction pad for holding the substrate by vacuum suction (see Patent Document 1).

### PRIOR ART DOCUMENTS

### Patent Documents

Patent Document 1: Japanese Laid-open Patent Publication No. 2011-029388

### SUMMARY

The present disclosure provides a mounting pad capable of reducing sticking of a substrate to a mounting mechanism, a mounting mechanism, and a substrate transfer mechanism.

In accordance with an aspect of the present disclosure, there is a mounting pad for placing an object thereon, comprising: a base; and an annular outer edge portion that is provided on one surface of the base, projects in a direction intersecting a surface direction of said one surface to surround an outer edge of said one surface, and is to be in contact with the object, wherein a thickness of the outer edge portion in at least one portion of the outer edge portion is different from a thickness of the outer edge portion in other portions of the outer edge portion.

### BRIEF DESCRIPTION OF THE DRAWINGS

FIG. 1 shows an example of a processing system according to a first embodiment of the present disclosure.

FIGS. 2A and 2B show an example of a relative position of a substrate and a mounting mechanism of an atmospheric transfer robot in the first embodiment.

FIG. 3 shows an example of a cross section near a mounting pad of the mounting mechanism according to the first embodiment.

FIG. 4 shows the mounting pad according to the first embodiment and an example of its modification.

FIG. 5 shows an example of a modification of the mounting pad.

FIG. 6 shows an example of a modification of the mounting pad.

FIG. 7 shows an example of an image of a deformed mounting pad.

FIG. 8 shows an example of separation start points of a substrate by teeth.

FIG. 9 shows an example of the relationship between the teeth and the direction of the mounting pad.

FIG. 10 shows an example of the relationship between the center of the substrate and the direction of the mounting pad.

FIG. 11 shows an example of modification of the mounting pad in Modification 1.

FIG. 12 shows an example of the relative position of the mounting mechanism, the substrate, and a support in Modification 2.

FIG. 13 shows another example of a cross section near a mounting pad of a mounting mechanism in Modification 3.

FIG. 14 shows an example of a cross section near a mounting pad of a mounting mechanism according to a second embodiment.

FIG. 15 shows an example of the mounting pad according to the second embodiment.

FIG. 16 shows an example of displacement of an outer edge portion of the mounting pad.

FIG. 17 shows an example of a mounting pad in Modification 4.

FIG. 18 shows an example of the displacement amount in the Z-axis direction in the second embodiment and modification 4.

FIG. 19 is a graph showing an example of the displacement amount in a radial direction in the second embodiment and Modification 4.

FIG. 20 shows an example of a mounting pad in Modification 5.

FIG. 21 shows an example of a mounting pad in modification 6.

FIG. 22 shows an example of a mounting pad according to Modification 7.

### DETAILED DESCRIPTION

Hereinafter, embodiments of a mounting pad, a mounting mechanism, and a substrate transfer mechanism of the present disclosure will be described in detail with reference to the accompanying drawings. The following embodiments are not intended to limit the present disclosure.

A substrate transfer mechanism in an atmosphere transfer chamber places a substrate on a teeth by releasing vacuum attraction and moving a mounting mechanism downward in a container accommodating a plurality of substrates, for example. The teeth is a table on which a substrate is placed in the container accommodating a plurality of substrates. In this case, it is required to quickly separate the substrate from a vacuum suction pad of the mounting mechanism. However, even if the vacuum attraction is released, the substrate may be stuck to the vacuum suction pad. If the transfer arm attempts to transfer another substrate in that state, the transfer arm moves to receive a next substrate in a state where a previous substrate is attracted to the mounting mechanism. Thus, the substrates may collide and be broken, or the previous substrate that is still attracted may fall during the transfer operation, causing a transfer error. Therefore, it is expected to reduce sticking of the substrate to the mounting mechanism.

### First Embodiment

[Configuration of Processing System]

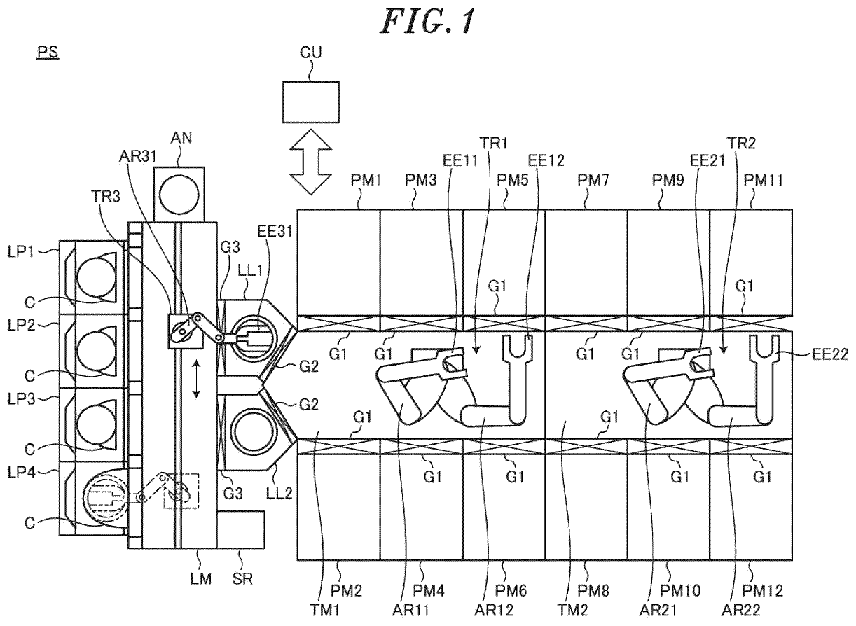

FIG. 1 shows an example of a processing system according to a first embodiment of the present disclosure. As shown in FIG. 1, a processing system PS can perform various treatments such as plasma processing and the like on a substrate. The processing system PS includes vacuum transfer modules TM1 and TM2, process modules PM1 to PM12, load-lock modules LL1 and LL2, an atmospheric transfer module LM, an aligner AN, a storage SR, and the like.

Each of the vacuum transfer modules TM1 and TM2 has a substantially rectangular shape in plan view. The process modules PM1 to PM6 are connected to two opposite side surfaces of the vacuum transfer module TM1. The load-lock modules LL1 and LL2 are connected to one of two opposite side surfaces of the vacuum transfer module TM1, and a path (not shown) for connection to the vacuum transfer module TM2 is connected to the other side surface thereof. The side surfaces of the vacuum transfer module TM1 to which the load-lock modules LL1 and LL2 are connected are angled by the two load-lock modules LL1 and LL2. The process modules PM7 to PM12 are connected to two opposite side surfaces of the vacuum transfer module TM2. A path (not shown) for connection to the vacuum transfer module TM1 is connected to one of two opposite side surfaces of the vacuum transfer module TM2. The vacuum transfer modules TM1 and TM2 have vacuum chambers in a vacuum atmosphere, and vacuum transfer robots TR1 and TR2 are disposed therein, respectively.

The vacuum transfer robots TR1 and TR2 are configured to be rotatable, extensible/contractible, and vertically movable. The vacuum transfer robots TR1 and TR2 transfer an object to be transferred based on an operation instruction outputted by a controller CU to be described later. For example, the vacuum transfer robot TR1 holds an object to be transferred at mounting mechanisms EE11 and EE12 disposed at the tip end thereof, and transfers the object to be transferred between the load-lock modules LL1 and LL2, the process modules PM1 to PM6, and the path (not shown). For example, the vacuum transfer robot TR2 holds an object to be transferred at mounting mechanisms EE21 and EE22 disposed at the tip end thereof, and transfers the object between the process modules PM7 to PM12 and the path (not shown). The mounting mechanism is also referred to as an end effector, a pick, or a fork.

The object to be transferred includes a substrate and a consumable part. The substrate is, e.g., a semiconductor wafer. The consumable part is replaceably attached to the process modules PM1 to PM12, and consumed by performing various processing such as plasma processing and the like in the process modules PM1 to PM12. The consumable part includes, e.g., members constituting a shower head and a ring assembly disposed in the process modules PM1 to PM12.

The process modules PM1 to PM12 have processing chambers, and stages (mounting table) are disposed therein. After substrates are placed on the stages, the process modules PM1 to PM12 are depressurized to introduce a processing gas. Then, an RF power is applied to generate plasma, and the substrate is subjected to plasma processing using the plasma. The vacuum transfer modules TM1 and TM2 and the process modules PM1 to PM12 are separated by gate valves G1 that can be opened and closed.

The load-lock modules LL1 and LL2 are disposed between the vacuum transfer module TM1 and the atmospheric transfer module LM. Each of the load-lock modules LL1 and LL2 has a chamber of which inner pressure can be switched between a vacuum state and an atmospheric pressure. A stage is disposed in each of the load-lock modules LL1 and LL2. In the case of loading the substrates from the atmospheric transfer module LM to the vacuum transfer module TM1, the substrates are transferred from the atmospheric transfer module LM into the load-lock modules LL1 and LL2 maintained at an atmospheric pressure; the pressures in the load-lock modules LL1 and LL2 are decreased; and the substrates are loaded into the vacuum transfer module TM1. In the case of unloading the substrates from the vacuum transfer module TM1 to the atmosphere transfer module LM, the substrates are transferred from the vacuum transfer module TM1 into the load-lock modules LL1 and LL2 maintained in a vacuum state; the pressures in the load-lock modules LL1 and LL2 are increased to an atmospheric pressure; and the substrates are loaded into the atmospheric transfer module LM. The load-lock modules LL1 and LL2 and the vacuum transfer module TM1 are separated by gate valves G2 that can be opened and closed. The load-lock modules LL1 and LL2 and the atmospheric transfer module LM are separated by gate valves G3 that can be opened and closed.

The atmospheric transfer module LM is disposed to be opposite to the vacuum transfer module TM1. The atmospheric transfer module LM may be, e.g., an equipment front end module (EFEM). The atmospheric transfer module LM is a rectangular parallelepiped-shaped atmospheric transfer chamber having a fan filter unit (FFU) and maintained at an atmospheric pressure. The two load-lock modules LL1 and LL2 are connected to one long side of the atmospheric transfer module LM. Load ports LP1 to LP4 are connected to the other long side of the atmospheric transfer module LM. A container C accommodating a plurality of (e.g., twenty five) substrates is placed on each of the load ports LP1 to LP4. The container C may be, e.g., a front opening unified pod (FOUP). An atmospheric transfer robot TR3 for transferring an object to be transferred is disposed in the atmospheric transfer module LM.

The atmospheric transfer robot TR3 is configured to be movable along the longitudinal direction of the atmospheric transfer module LM, and is configured to be rotatable, extensible/contractible, and vertically movable. The atmospheric transport robot TR3 transfers an object to be transferred based on the operation instruction outputted by the controller CU to be described later. For example, the atmospheric transfer robot TR3 holds an object to be transferred at a mounting mechanism EE31 disposed at the tip end thereof, and transfers the object to be transferred between the load ports LP1 to LP4, the load-lock modules LL1 and LL2, the aligner AN, and the storage SR.

The aligner AN is connected to one short side surface of the atmospheric transfer module LM. Alternatively, the aligner AN may be connected to the long side surface of the atmospheric transfer module LM. Alternatively, the aligner AN may be disposed in the atmospheric transfer module LM. The aligner AN has a support (not shown), an optical sensor (not shown), and the like. Here, the aligner is a device for detecting the position of the object to be transferred.

The support is a table that is rotatable about an axis extending in a vertical direction, and is configured to support a substrate thereon. The support is rotated by a driving device (not shown). The driving device is controlled by the controller CU to be described later. When the support is rotated by the power from the driving device, the substrate placed on the support is also rotated.

The optical sensor detects the edge of the substrate while the substrate is rotating. The optical sensor detects the deviation amount of the notch (or another marker) of the substrate with respect to a reference angular position, and the deviation amount of the center position of the substrate with respect to a reference position from the edge detection result. The optical sensor outputs the deviation amount of the angular position of the notch and the deviation amount of the center position of the substrate to the controller CU to be described later. The controller CU calculates the rotation amount of a rotary support for correcting the angular position of the notch to the reference angular position based on the deviation amount of the angular position of the notch. The controller CU controls a driving device (not shown) to rotate the rotary support by the rotation amount. Accordingly, the angular position of the notch can be corrected to the reference angular position. Further, the controller CU controls the position of the mounting mechanism EE31 of the atmospheric transfer robot TR3 at the time of receiving the substrate from the aligner AN such that the center position of the substrate coincides with a predetermined position on the mounting mechanism EE31 of the atmospheric transfer robot TR3 based on the deviation amount of the center position of the substrate.

The storage SR is connected to the long side surface of the atmospheric transfer module LM. Alternatively, the storage SR may be connected to the short side surface of the atmospheric transfer module LM. Alternatively, the storage SR may be disposed in the atmospheric transfer module LM. The storage SR accommodates an object to be transferred.

The processing system PS includes the controller CU. The controller CU may be, e.g., a computer. The controller CU includes a central processing unit (CPU), a random access memory (RAM), a read only memory (ROM), an auxiliary storage device, and the like. The CPU operates based on a program stored in the ROM or the auxiliary storage device to control the individual components of the processing system PS. For example, the controller CU outputs the operation instruction to the vacuum transfer robots TR1 and TR2, the atmospheric transfer robot TR3, and the like. The operation instruction includes, e.g., an instruction for holding objects to be transferred at the mounting mechanisms EE11, EE12, EE21, EE22, and EE31 disposed at the tip ends and transferring the objects to be transferred between modules.

[Specific Description of Mounting Mechanism EE31]

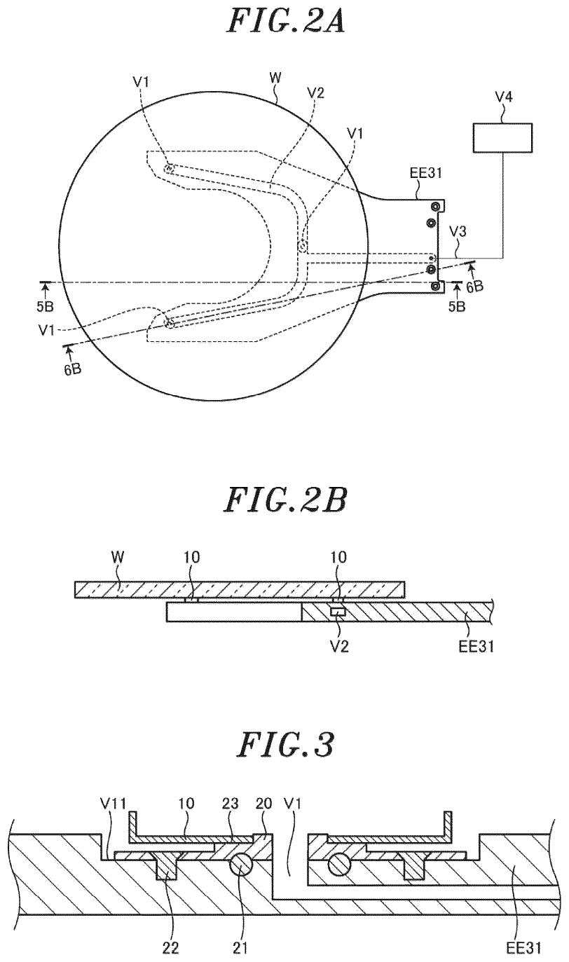

Next, the mounting mechanism EE31 of the atmospheric transfer robot TR3 will be described in detail with reference to FIGS. 2A, 2B, and 3. FIGS. 2A and 2B show an example of the relative position of the substrate and the mounting mechanism of the atmospheric transfer robot in the first embodiment. FIG. 2A is a plan view of the mounting mechanism EE31 holding the substrate W. FIG. 2B is a cross-sectional view of the mounting mechanism EE31 holding the substrate W, and shows a cross section taken along the dash-dotted line 5B-5B of FIG. 2A.

The mounting mechanism EE31 has a substantially U-shape in plan view. The mounting mechanism EE31 includes a plurality of suction holes V1, a suction passage V2, and the like. The suction passage V2 is an example of an exhaust passage. The mounting mechanism EE31 holds the bottom surface of the substrate W by vacuum suction using the suction holes V1. A mounting pad 10 is disposed in each suction hole V1. The mounting pad 10 is made of, e.g., engineering plastic, and the mounting direction of the mounting pad 10 can be changed. Further, the mounting pad 10 can be replaced. The suction holes V1 are connected to an exhaust device V4 through the suction passage V2 and an exhaust line V3. The exhaust device V4 includes a valve, a regulator, a vacuum pump, and the like, and adjusts the pressure in the suction passage V2 and the exhaust line V3 by conducting suction from the suction passage V2 and the exhaust line V3.

FIG. 3 shows an example of a cross section near the mounting pad of the mounting mechanism in the first embodiment. FIG. 3 shows a part of the cross section taken along the dash-dotted line 6B-6B of FIG. 2A. As shown in FIG. 3, the mounting pad 10 is attached to a pad mounting portion V11 corresponding to the suction hole V1 and disposed on one surface (for example, upper surface) of the mounting mechanism EE31 via a bracket 20. The bracket 20 is fastened to the mounting mechanism EE31 with a screw 22 while maintaining airtightness of the suction hole V1 by an O-ring 21. The mounting pad 10 is fastened to the bracket 20 with a screw (not shown). The mounting pad 10 may be adhered to the bracket 20 at a portion 23 in contact with the bracket 20. In this case, a screw hole (not shown) is not required, so the area of the base 11 of the mounting pad 10 can be reduced.

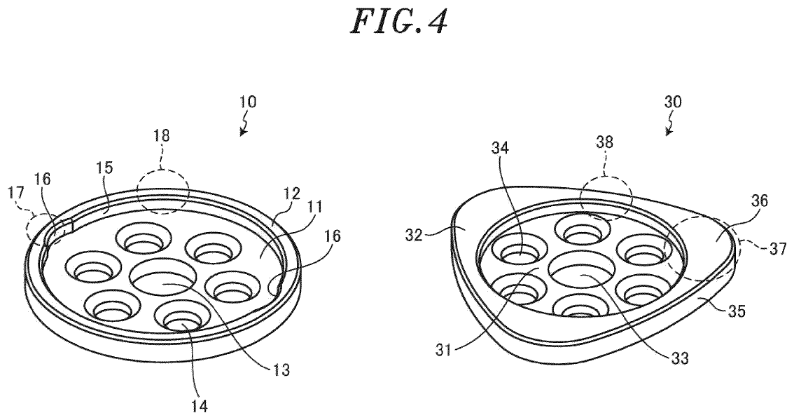

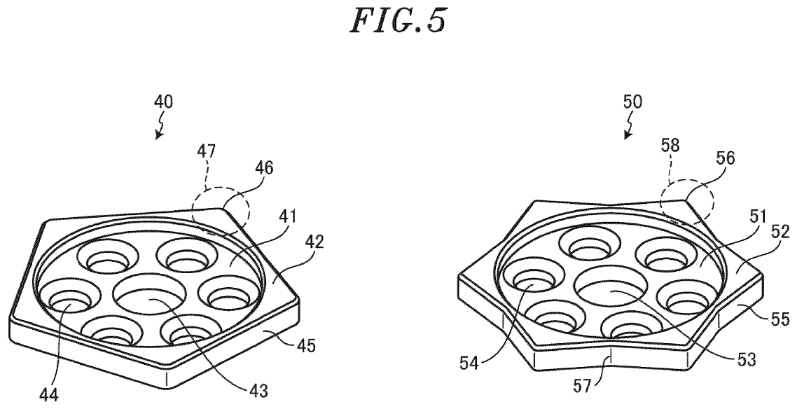

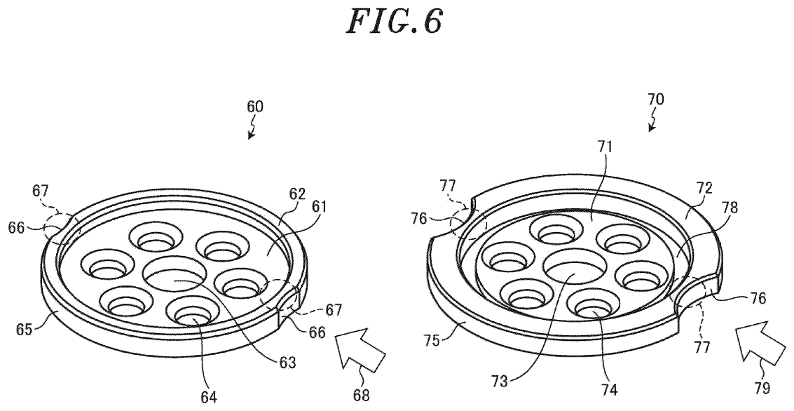

Next, the mounting pad 10 and modifications thereof will be described with reference to FIGS. 4 to 6. FIG. 4 shows the mounting pad according to the first embodiment and an example of a modification thereof. FIGS. 5 and 6 show examples of the modification of the mounting pad.

The mounting pads 10 and 30 shown in FIG. 4 have portions where the thickness of the outer edge portion is not uniform in the circumferential direction of the outer edge portion, so that the separation start points are generated. The thickness of the outer edge portion is the dimension between the inner part and the outer part of the outer edge portion. The mounting pad 10 has an annular outer edge portion 12 higher than a circular base 11. In other words, the outer edge portion 12 is disposed on one surface of the base 11, projects in a direction intersecting the surface direction of the corresponding surface to surround the outer edge of the corresponding surface, and has an annular shape so as to be in contact with the object (the substrate W). Here, the direction intersecting the surface direction of the corresponding surface may be a direction of 30° to 150° with respect to the corresponding surface, or a direction of 60° to 120° with respect to the corresponding surface, or a direction substantially perpendicular to the one surface (direction of about 90°), or a direction of 90° with respect to the corresponding surface. Accordingly, when the substrate W is vacuum attracted by the mounting pad 10, the space of the base 11 surrounded by the outer edge portion 12 is sucked. The mounting pad 10 has an opening 13 at the center of the base 11. The opening 13 communicates with the suction holes V1 and the suction passage V2 through the bracket 20. Further, the base 11 has a plurality of screw holes 14 on the outer peripheral side of the opening 13. The opening 13 and the screw holes 14 are examples of a through-hole. The hole diameter of the through-hole is preferably ϕ1 to 5 mm, and more preferably ϕ2 to 3 mm.

The mounting pad 10 is fastened to the bracket 20 with screws (not shown) corresponding to the screw holes 14. In the mounting pad 10, six screw holes 14 are provided and the base 11 has a circular shape. However, the present disclosure is not limited thereto. For example, three screw holes 14 may be provided and the base 11 may have a triangular shape. In the mounting pad 10, one or more recesses 16 are disposed on the inner circumferential surface 15 side of the outer edge portion 12. In the example of FIG. 4, two recesses 16 are disposed at opposing positions. Two or more portions (the recesses 16) where the outer edge portion 12 has a different thickness may be provided at rotationally symmetrical positions with the center of the base 11 as the rotation axis. In the mounting pad 10, the thickness of the outer edge portion 12, that is, the thickness of the outer edge portion 12 in contact with the substrate W, is different between regions 17 where the recesses 16 exist and a region 18 where the recess 16 does not exist. In other words, the thickness of the outer edge portion 12 in at least one portion (the regions 17) of the outer edge portion 12 is different from that in another portion (the region 18) of the outer edge portion 12. In the case of the mounting pad 10, the regions 17 serve as the separation start points. In other words, in the mounting pad 10, the sticking of the substrate W to the mounting mechanism EE31 can be reduced by providing the recesses 16.

The mounting pad 30 is an example of modification of the mounting pad 10. The mounting pad 30 has an annular outer edge portion 32 higher than a circular base 31. Similarly to the mounting pad 10, the mounting pad 30 has an opening 33 at the center of the base 31, and a plurality of screw holes 34 are disposed on the outer peripheral side of the opening 33. Similarly to the mounting pad 10, the mounting pad 30 is fastened to the bracket 20 with screws (not shown) corresponding to the screw holes 34. The mounting pad 30 has one or more protrusions 36 on an outer circumferential surface 35 side of the outer edge portion 32. In the example of FIG. 4, three protrusions 36 are disposed at equal intervals in the circumferential direction, and have a triangular shape with rounded corners. In the mounting pad 30, the thickness of the outer edge portion 32, that is, the thickness of the outer edge portion 32 in contact with the substrate W, is different between regions 37 where the protrusions 36 exist and regions 38 where the protrusion 36 does not exist. In the case of the mounting pad 30, the regions 38 serve as the separation start points. In other words, in the mounting pad 30, the sticking of the substrate W to the mounting mechanism EE31 can be reduced by providing the regions 38.

The mounting pads 40 and 50 shown in FIG. 5 have corners on the outer circumferential side of the outer edge portion, so that the separation start points are generated. The mounting pads 40 and 50 also have portions where the thickness of the outer edge portion in contact with the substrate W is not uniform in the circumferential direction of the outer edge portion. The mounting pad 40 has an annular outer edge portion 42 higher than a circular base 41. Similarly to the mounting pad 10, the mounting pad 40 has an opening 43 at the center of the base 41, and a plurality of screw holes 44 are disposed on the outer peripheral side of the opening 43. Similarly to the mounting pad 10, the mounting pad 40 is fastened to the bracket 20 with screws (not shown) corresponding to the screw holes 44. The mounting pad 40 has one or more corners 46 on an outer circumferential surface 45 side of the outer edge portion 42. In the example of FIG. 5, five corners 46 are provided at equal intervals in the circumferential direction, and the outer edge portion 42 has a pentagonal outer shape. In other words, the outer edge portion 42 has a circular inner circumferential surface and an outer circumferential surface formed as a flat surface with the corner 46. Alternatively, the outer edge portion 42 may have an elliptical inner circumferential surface. The outer shape of the outer edge portion 42 is not limited to a pentagonal shape, and may be a polygonal shape. In the mounting pad 40, the corners 46 serve as the separation start points, so that the separation of the substrate W becomes easier. Also in the mounting pad 40, the thickness of the outer edge portion 42, that is, the thickness of the outer edge portion 42 in contact with the substrate W, is different between regions 47 where the corners 46 exist and regions where the corners 46 do not exist, so that the regions 47 or the regions where the corners 46 does not exist may be the separation start point.

The mounting pad 50 has an annular outer edge portion 52 higher than a circular base 51. Similarly to the mounting pad 10, the mounting pad 50 has an opening 53 at the center of the base 51, and a plurality of screw holes 54 are disposed on the outer peripheral side of the opening 53. Similarly to the mounting pad 10, the mounting pad 50 is fastened to the bracket 20 with screws (not shown) corresponding to the screw holes 54. The mounting pad 50 has one or more corners 56 on an outer circumferential surface 55 side of the outer edge portion 52. In the example of FIG. 5, six corners 56 are disposed at equal intervals in the circumferential direction. The angles of the corners 56 are smaller than those of the corners 46 of the mounting pad 40. A line 57 exists between the corners 56 of the outer circumferential surface 55 to connect both surfaces. In other words, the outer shape of the outer edge portion 52 is a star shape. In the mounting pad 50, the separation of the substrate W becomes easier by providing the corners 56 that are the separation start points. Also in the mounting pad 50, the thickness of the outer edge portion 52, that is, the thickness of the outer edge portion 52 in contact with the substrate W, is different between regions 58 where the corners 56 exist and the regions where the corners 56 do not exist, for example, the regions where the lines 57 exist. Therefore, the regions 58 or the regions where the lines 57 exist may be the separation start points.

In the mounting pads 60 and 70 shown in FIG. 6, the recesses are formed as deformation points on the outer circumferential side of the outer edge portion. Accordingly, the entire mounting pad is easily deformed at the separation start points. The mounting pads 60 and 70 also have portions where the thickness of the outer edge portion in contact with the substrate W is not uniform in the circumferential direction of the outer edge portion. The mounting pad 60 has an annular outer edge portion 62 higher than the circular base 61. Similarly to the mounting pad 10, the mounting pad 60 has an opening 63 at the center of the base 61, and a plurality of screw holes 64 are disposed on the outer peripheral side of the opening 63. Similarly to the mounting pad 10, the mounting pad 60 is fastened to the bracket 20 with screws (not shown) corresponding to the screw holes 64. The mounting pad 60 has one or more recesses 66 on an outer circumferential surface 65 side of the outer edge portion 62. In the example of FIG. 6, two recesses 66 are disposed at opposing positions. Since the mounting pad 60 has the recesses 66, the mounting pad 60 is deformed at the recesses 66.

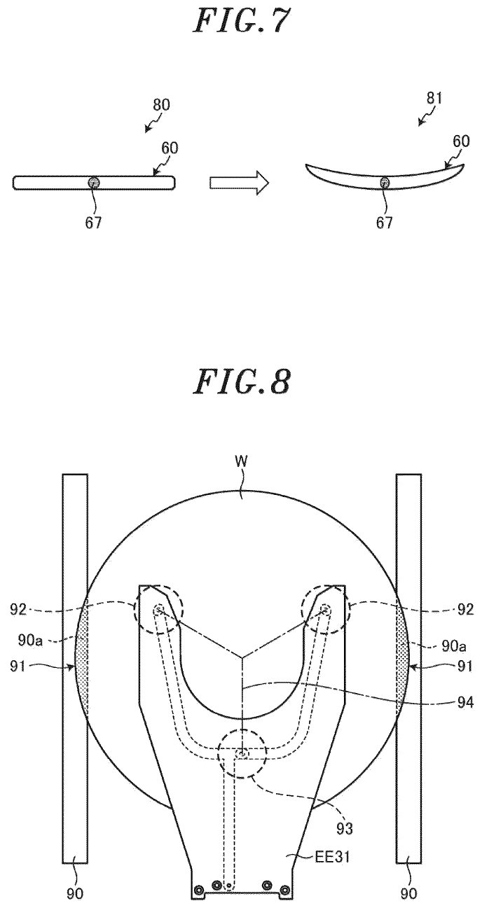

Here, the deformation of the mounting pad 60 in a direction of an arrow 68 will be described with reference to FIG. 7. FIG. 7 shows an example of an image of a deformed mounting pad. As shown in FIG. 7, when the mounting pad 60 is viewed from the side at the time of placing the substrate W by the mounting mechanism EE31, the mounting pad 60 is deformed in a downwardly projecting shape with respect to regions 67 where the recesses 66 disposed at opposing positions exist from a state 80 to a state 81. In this case, the regions 67 are first separated from the substrate W compared to the other portions. In other words, in the mounting pad 60, the regions 67 where the recesses 66 exist serve as the separation start points, so that the separation of the substrate W become easier. Also in the mounting pad 60, the thickness of the outer edge portion 62, that is, the thickness of the outer edge portion in contact with the substrate W, is different between the regions 67 where the recesses 66 exist and the region where the recess 66 does not exist. Therefore, the regions 67 may serve as the separation start points.

Referring back to the description of FIG. 6, the mounting pad 70 has an annular outer edge portion 72 higher than a circular base 71. Similarly to the mounting pad 10, the mounting pad 70 has an opening 73 at the center of the base 71, and a plurality of screw holes 74 are disposed on the outer peripheral side of the opening 73. Similarly to the mounting pad 10, the mounting pad 70 is fastened to the bracket 20 with screws (not shown) corresponding to the screw holes 74. The mounting pad 70 has one or more recesses 76 on an outer circumferential surface 75 side of the outer edge portion 72. In the example of FIG. 6, two recesses 76 are disposed at opposing positions. Further, the mounting pad 70 has an annular groove 78 formed near the boundary between the base 71 and the outer edge portion 72. Since the mounting pad 70 has the recesses 76 and the groove 78, the mounting pad 70 can be easily deformed at the recesses 76. The deformation of the mounting pad 70 in a direction of an arrow 79 is the same as the deformation of the mounting pad 60 shown in FIG. 7. In other words, in the mounting pad 70, regions 77 where the recesses 76 exist serve as the separation start points, so that the separation of the substrate W becomes easier. Also in the mounting pad 70, the thickness of the outer edge portion 72, that is, the thickness of the outer edge portion in contact with the substrate W, is different between the regions 77 where the recesses 76 exist and the region where the recess 76 does not exist, so that the regions 77 may serve as the separation start points. Further, in the mounting pads 60 and 70, the screw holes 64 and 74 distant from the regions 67 and 77 that are the deformation points, for example, the screw holes 64 and 74 spaced apart from the regions 67 and 77 by 90° in the circumferential direction may be omitted to make the deformation of the mounting pads easier.

Next, the relationship between the teeth 90 and the directions of various mounting pads and the relationship between the center of the substrate W and the directions of the various mounting pads will be described with reference to FIGS. 8 to 10. FIG. 8 shows an example of separation start points of a substrate by teeth. FIG. 8 shows a state in which the substrate W is placed on the teeth 90 of the container C placed on the load port LP1, for example. In FIG. 8, when the mounting mechanism EE31 is moved downward, both ends of the substrate W are brought into contact with the teeth 90, and the contact points serve as separation start points 91. At this time, the separation start points of the mounting pad may have different directions at tip ends 92 and a base 93 of the mounting mechanism EE31. Both the tip ends 92 and the base 93 serve as the separation start points because the symmetry of the mounting pad at the suction holes V1 is lost. It is assumed that the distances from the suction holes V1 corresponding to the tip ends 92 and the base 93 to the center of the substrate W are the same. A line 94 connects the center of the substrate W and the suction holes V1 corresponding to the base 93. Regions 90a represent portions where the substrate W can be in contact with the teeth 90.

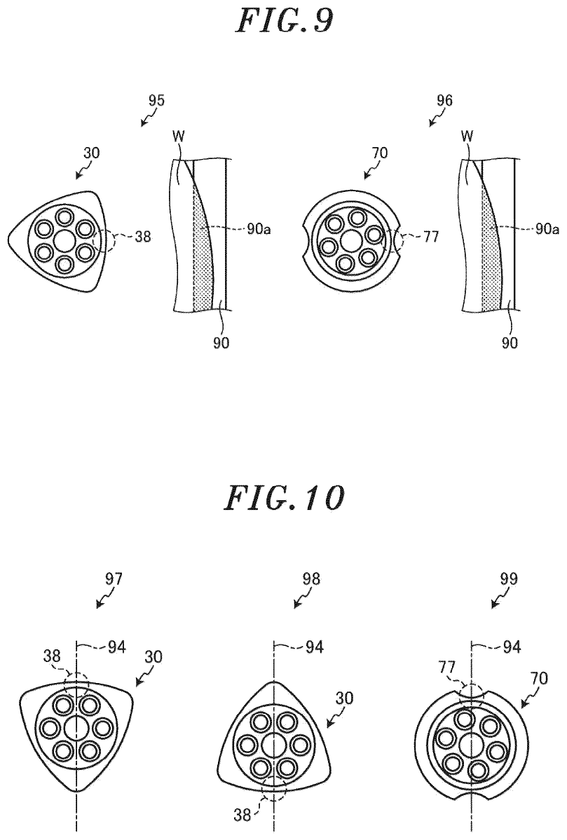

FIG. 9 shows an example of the relationship between the teeth and the direction of the mounting pad. Examples 95 and 96 shown in FIG. 9 show examples of the direction of the separation start point at the tip end 92 on the right side of FIG. 8. The tip end 92 on the left side of FIG. 8 is bilaterally symmetrical with the tip end 92 on the right side, so that the description thereof will be omitted. In the examples 95 and 96, three or more mounting pads 30 and 70 are spaced apart from the center of the substrate W by the same distance, as shown in FIG. 8. In the example 95, when the mounting pad 30 is used, the region 38 face the teeth 90. In the example 96, when the mounting pad 70 is used, the region 77 faces the teeth 90. In other words, at least two mounting pads 30 or 70 are disposed such that the position (the region 38) of the outer edge portion 32 or the position (the region 77) of the outer edge portion 72 where the thickness of the outer edge portion in contact with the substrate W that is an object to be transferred is smallest faces the teeth 90. The direction of the teeth 90 includes the direction of a range in which the extension line of the straight line that connects the center of the mounting pad 30 or 70 and the region 38 or 77 passes through the region 90a. In other words, the mounting pad 30 or 70 is disposed such that at least one of the thinnest portions of the outer edge portion 32 or 72 of the mounting pad 30 or 70 faces a portion (region 90a) where the substrate W placed on the mounting mechanism EE31 can be in contact with the teeth 90 that is a table. In other words, in the examples 95 and 96, the separation start points 91 of the teeth 90a are close to the regions 38 and 77 of the mounting pads 30 and 70 that are the separation start points, so that the sticking of the substrate W can be reduced. At the tip ends 92 of FIG. 8, the direction of the center of the substrate W is different from the directions of the separation start points of the mounting pads 30 and 70.

FIG. 10 shows an example of the relationship between the center of the substrate and the direction of the mounting pad. On the other hand, examples 97 to 99 shown in FIG. 10 show examples of the direction of the separation start point at the base 93. In the example 97, when the mounting pad 30 is used, the region 38 is located on the line 94 indicating the center direction of the substrate W, and faces the center of the substrate W. In an example 98, when the mounting pad 30 is used, the region 38 is located on the line 94 indicating the center direction of the substrate W, and faces the outer edge portion side of the substrate W. In other words, the example 98 shows a state in which the mounting pad 30 of the example 97 is rotated by 180°. In the example 99, when the mounting pad 70 is used, the region 77 is located on the line 94 indicating the center direction of the substrate W. In other words, at least one mounting pad 30 or 70 is disposed such that the position (the region 38 or 77) of the outer edge portion 32 or 72 where the thickness of the outer edge portion in contact with the substrate W is smallest is located on the straight line that connects the center of the substrate W and the mounting pad 30 or 70. In other words, in the examples 97 to 99, the sticking of the substrate W can be reduced by aligning the center of the substrate W with the directions of the regions 38 and 77 of the mounting pads 30 and 70 that serve as the separation starting points.

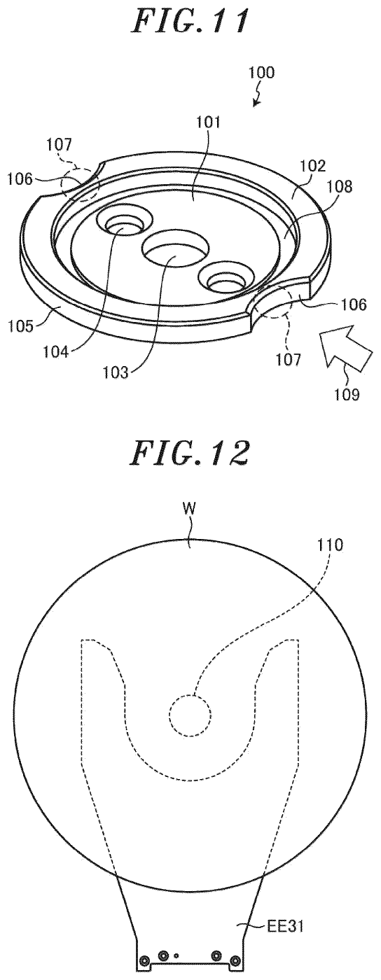

Next, Modifications 1 to 3 will be described with reference to FIGS. 11 to 13. FIG. 11 show an example of modification of the mounting pad in Modification 1. In a mounting pad 100 of Modification 1 shown in FIG. 11, similarly to the mounting pad 70, recesses are formed as deformation points on the outer circumferential side of the outer edge portion. Therefore, the entire mounting pad is easily deformed at the separation start points. The mounting pad 100 also has a portion where the thickness of the outer edge portion in contacts with the substrate W is not uniform in the circumferential direction of the outer edge portion.

The mounting pad 100 has an annular outer edge portion 102 higher than a circular base 101. Similarly to the mounting pad 10, the mounting pad 100 has an opening 103 at the center of the base 101, and a plurality of screw holes 104 are disposed on the outer peripheral side of the opening 103. Similarly to the mounting pad 10, the mounting pad 100 is fastened to the bracket 20 with screws (not shown) corresponding to the screw holes 104. The mounting pad 100 has one or more recesses 106 on an outer circumferential surface 105 side of the outer edge portion 102. In the example of FIG. 11, two recesses 106 are formed at opposing positions. Further, two screw holes 104 are disposed on a straight line that connects the two opposing recesses 106. In other words, in the mounting pad 100, the portions (the recesses 106) where the thickness of the outer edge portion 102 is different, and the through-holes (the opening 103 and the screw holes 104) are disposed on a straight line. Further, in the mounting pad 100, an annular groove 108 is formed near the boundary between the base 101 and the outer edge portion 102. Since the mounting pad 100 has the recesses 106 and the groove 108, the mounting pad 100 can be more easily deformed at the recesses 106. The deformation of the mounting pad 100 in a direction of an arrow 109 is the same as the deformation of the mounting pad 60 shown in FIG. 7. In other words, in the mounting pad 100, the regions 107 where the recesses 106 exist serve as the separation start points, and the separation of the substrate W becomes easier. Also in the mounting pad 100, the thickness of the outer edge portion 102, that is, the thickness of the outer edge portion in contact with the substrate W, is different between the regions 107 where the recesses 106 exist and the region where the recess 106 does not exist. Thus, the regions 107 may serve as the separation start points.

FIG. 12 shows an example of the relative positions of a mounting mechanism, a substrate, and a support in Modification 2. A support 110 of Modification 2 shown in FIG. 12 is a support for the aligner AN, and has the mounting pad 10 at the center thereof similarly to the mounting mechanism EE31. In other words, the support 110 is an example of a mounting mechanism. In FIG. 12, the illustration of the mounting pad 10 is omitted. FIG. 12 shows a state in which the substrate W placed on the mounting mechanism EE31 is transferred to the support 110 of the aligner AN. In the support 110, similarly to the mounting mechanism EE31, the suction holes (not shown) of the mounting pad 10 are connected to an exhaust device through a suction passage and an exhaust line, thereby attracting and holding the substrate W. In the case of unloading the substrate W from the aligner AN, when the substrate W is lifted by the mounting mechanism EE31, the recesses 16 of the mounting pad 10 serve as the separation start points, so that the sticking of the substrate W to the support 110 can be reduced.

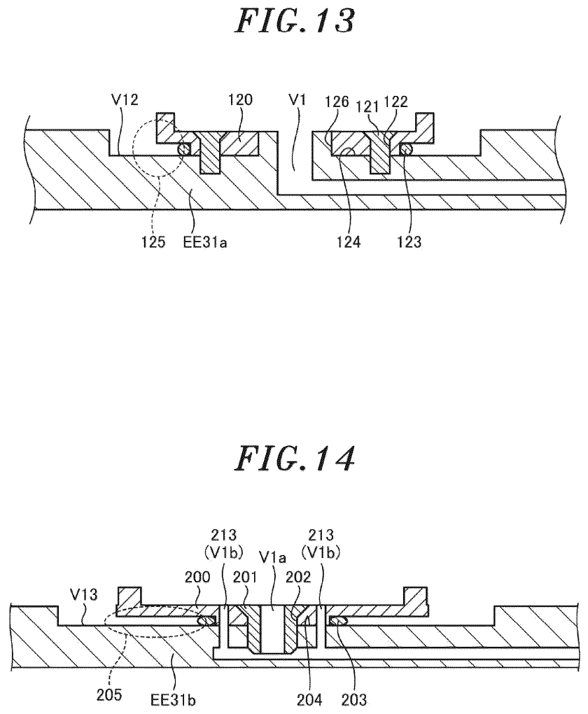

FIG. 13 shows another example of a cross section near a mounting pad of a mounting mechanism according to Modification 3. As shown in FIG. 13, a mounting pad 120 of Modification 3 is attached by screws 121 to a pad mounting portion V12 corresponding to the suction hole V1 and disposed on one surface (for example, upper surface) of a mounting mechanism EE31a. The mounting pad 120 has an opening 126 at the center thereof, and the opening 126 is connected to the upper part of the suction hole V1. An O-ring 123 as a seal member is disposed on the back surface of the mounting pad 120 (corresponding to the back surface of the base 11) and at the outer peripheral portions of mounting holes 122 for the screws 121. The screw 121 is an example of a fastening member, and the mounting hole 122 is an example of a through-hole. In other words, in the mounting pad 120, at least one of the through-holes is a fastening hole for the fastening member (the screw 121). In the example of FIG. 13, the O-ring 123 as a seal member is disposed between the base of the mounting pad 120 and the pad mounting portion V12 to surround all the through-holes. By providing the O-ring 123 to surround the screws 121, the close contact between the mounting pad 120 and the pad mounting portion V12 can be ensured in the region 124 where the mounting pad 120 and the pad mounting portion V12 are in contact with each other from the center of the mounting pad 120 to the O-ring 123. Further, a gap 125 exists between the pad mounting portion V12 and the outer edge portion of the mounting pad 120 that is located on the outer peripheral side compared to the O-ring 123. Due to the gap 125, the mounting pad 120 can be bent, and the outer edge portion of the mounting pad 120 can be brought into close contact with the substrate W.

### Second Embodiment

In Modification 3, the opening 126 formed at the center of the mounting pad 120 and connected to the suction hole V1 and the mounting holes 122 of the mounting pad 120 are separately formed. However, the mounting pad may be attached to the mounting mechanism by a fastening member such as a screw having a through-hole or the like. Such an embodiment will be described as a second embodiment. The processing system in the second embodiment is the same as that in the above-described first embodiment, so that the redundant description of configurations and operations will be omitted.

FIG. 14 shows an example of a cross section near a mounting pad of a mounting mechanism according to the second embodiment. As shown in FIG. 14, a mounting mechanism EE31b of the second embodiment includes a pad mounting portion V13, a mounting pad 200, and a screw 201 instead of the pad mounting portion V12, the mounting pad 120, and the screws 121 of Modification 3. The mounting mechanism EE31b of the second embodiment has a suction hole V1a formed in the screw 201 and a plurality of suction holes V1b formed in the mounting pad 200 instead of the suction hole V1 of Modification 3. The suction hole V1a is an example of a first through-hole.

The mounting pad 200 is attached with the screw 201 to the pad mounting portion V13 disposed on one surface (for example, upper surface) of the mounting mechanism EE31b. The mounting pad 200 is fastened with the screw 201 to the mounting mechanism EE31b at an opening 202 formed at the center of the mounting pad 200. The screw 201 is an example of a fastening member. The suction hole V1a is formed at the center of the screw 201 and communicates with the suction passage V2. In other words, the suction hole V1a of the screw 201 is an example of a second through-hole formed along the fastening direction of the screw 201. The mounting pad 200 has a plurality of through-holes 213 corresponding to the suction holes V1b to surround the opening 202. The through-hole 213 is an example of a second through-hole. The suction holes V1b communicates with the suction passage V2. In the following description, in a state where the mounting pad 200 is mounted on the mounting mechanism EE31b, the through-holes 213 and the suction holes V1b may be collectively referred to as the suction holes V1b. In the mounting pad 200, the pressure applied to the backside of the substrate W can be distributed by providing the suction holes V1b in addition to the suction hole V1a.

An O-ring 203 as a seal member is disposed on the back surface of the mounting pad 200 and at the outer peripheral portion of the suction hole V1b. In the example of FIG. 14, the O-ring 123 as a seal member is disposed between a base 211 (to be described later) of the mounting pad 200 and the pad mounting portion V13 to surround all the through-holes (the suction holes V1a and V1b). In other words, the O-ring 203 is an example of a seal member disposed between the base 211 of the mounting pad 200 and one surface of the mounting mechanism EE31b to surround all the through-holes (the suction holes V1a and V1b) in plan view. By providing the O-ring 203 to surround the suction holes V1a and V1b, the close contact between the mounting pad 200 and the pad mounting portion V13 can be ensured in the region 204 where the mounting pad 200 and the pad mounting portion V13 are in contact with each other from the center of the mounting pad 200 to the O-ring 203.

In addition, a gap 205 exists between the pad mounting portion V13 and the outer edge portion of the mounting pad 200 that is located on the outer peripheral side compared to the O-ring 203. The gap 205 has a longer distance from the O-ring 203 to the outer edge portion compared to the gap 125 in the mounting pad 120 of Modification 3, so that the mounting pad 200 can be bent more. Due to the gap 205, the outer edge portion of the mounting pad 200 can be brought into close contact with the substrate W. When the mounting mechanism EE31b transfers the substrate W to the teeth 90 or the like, the O-ring 203 serves as a cushion used when the mounting pad 200 adhered to the substrate W is separated and returns to its original position. Therefore, even if the mounting pad 200 is bent more, the O-ring 203 suppresses stress cracking of the mounting pad 200 and, thus, the lifespan of the mounting pad 200 can be increased.

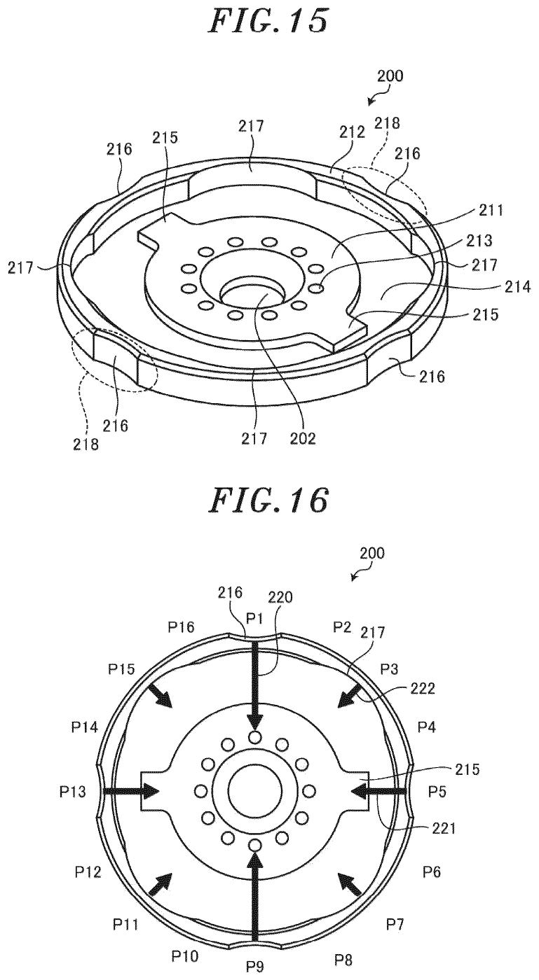

Next, the mounting pad 200 will be described in detail with reference to FIGS. 15 and 16. FIG. 15 shows an example of the mounting pad according to the second embodiment. The mounting pad 200 shown in FIG. 15 has recesses as deformation points on the outer circumferential side and the inner circumferential side of the outer edge portion. Hence, the entire mounting pad can be easily deformed at the separation start points. The mounting pad 200 also has a portion where the thickness of the outer edge portion in contact with the substrate W is not uniform in the circumferential direction of the outer edge portion. The mounting pad 200 has an annular outer edge portion 212 higher than a circular base 211. The mounting pad 200 has an opening 202 at the center of the base 211, and a plurality of through-holes 213 are disposed on the outer peripheral side of the opening 202. The through-holes 213 respectively communicate with the suction holes V1b on the mounting mechanism EE31b side when the mounting pad 200 is mounted on the pad mounting portion V13. In other words, one of the through-holes (the opening 202 and the through-hole 213) formed in the base 211 may be a fastening hole. For example, similarly to the mounting pad 200, the through-holes may include the opening 202 that is a through-hole formed at the center of the base 211, as a fastening hole, and other through-holes 213 formed around the opening 202. The opening 202 (first through-hole) as a fastening hole and the other through-hole 213 (second through-holes) may have different diameters. Here, the diameter indicates a diameter when the through-hole has a circular cross-sectional shape, and indicates a largest cross-sectional diameter when the through-hole has another shape. It is preferable that the diameter of the opening 202 that is a fastening hole is greater than the diameters of the other through-holes 213.

The mounting pad 200 has an annular groove 214 between the through-holes 213 of the base 211 and the outer edge portion 212. Protrusions 215 are formed at a part of the groove 214. The thickness of the protrusions 215 is the same as that of the vicinity of the through-holes 213 of the base, and is different from that of the groove 214 in the circumferential direction of the groove 214. In other words, the thickness (width) of the groove 214 in at least one portion (where the protrusions 215 are disposed) of the groove 214 is different from the thickness of other portions of the groove 214. Further, the protrusions 215 are disposed at positions facing each other with respect to the center on a straight line passing through the center of the mounting pad 200, for example.

The mounting pad 200 has one or more recesses 216 on the outer circumferential surface side of the outer edge portion 212. In other words, the recesses 216 are formed such that the outer circumference of the outer edge portion 212 becomes close to the center of the base 211 in at least one portion of the outer edge portion 212, and the distance between the outer circumference and the inner circumference of the outer edge portion 212 in the corresponding portion is smaller than that in the other portions of the outer edge portion 212. Further, the mounting pad 200 has one or more recesses 217 on the inner circumferential surface side of the outer edge portion 212. In other words, the recesses 217 are formed such that the inner circumference of the outer edge portion 212 becomes distant from the center of the base 211 in at least one portion of the outer edge portion 212, and the distance between the outer circumference and the inner circumference the outer edge portion 212 in the corresponding portion is smaller than that in the other portions of the outer edge portion 212. In the example of FIG. 15, four recesses 216 are arranged at intervals of 90° in the circumferential direction of the outer edge portion 212, and four recesses 217 are arranged at intervals of 90° while being shifted from the recesses 216 by 45° in the circumferential direction of the outer edge portion 212. In other words, the recesses 216 and 217 are alternately arranged along the circumferential direction of the outer edge portion 212. In the mounting pad 200, at least one portion (for example, the recesses 216) of the outer edge portion 212, at least one portion (for example, the protrusions 215) of the grooves 214, and the opening 202 may be disposed on a straight line.

In the mounting pad 200, regions 218 where two recesses 216 face the center of the mounting pad 200 without the protrusions 215 interposed therebetween among the four recesses 216 serve as the separation start points, so that the separation of the substrate W become easier. In other words, the mounting pad 200 is easily deformed at the two recesses 216 that do not face the protrusions 215 than at the two recesses 216 facing the protrusions 215.

FIG. 16 shows an example of displacement of the outer edge portion of the mounting pad. In FIG. 16, arrows 220 to 222 indicate the tendency of displacement (displacement in the XY-axis direction) of the outer edge portion 212 at positions P1 to P16 obtained by dividing the mounting pad 200 into sixteen parts in the circumferential direction in plan view. In FIG. 16, one of the recesses 216 that do not face the protrusions 215 is set to the position P1. The arrows 220 to 222 indicate the substantial displacement amount by the lengths of the arrows, and indicate the displacement direction by the directions of the arrows. The arrows 220 indicate the displacement at the positions P1 and P9. The arrows 221 indicate the displacement at the positions P5 and P13. The arrows 222 indicate the displacement at the positions P3, P7, P11 and P15. The arrows corresponding to positions P2, P4, P6, P8, P10, P12, P14, and P16 are omitted for simplicity of illustration.

As shown in FIG. 16, in the mounting pad 200, the displacement at the positions P1 and P9 indicated by the arrows 220 is largest, and the displacement at the positions P3, P7, P11 and P15 indicated by the arrows 222 is smallest. As described above, in the mounting pad 200, the displacement applied to the contact surface between the outer edge portion 212 and the substrate W is shifted, so that the positions P1 and P9 serve as the separation start points, which makes the separation of the substrate W easier.

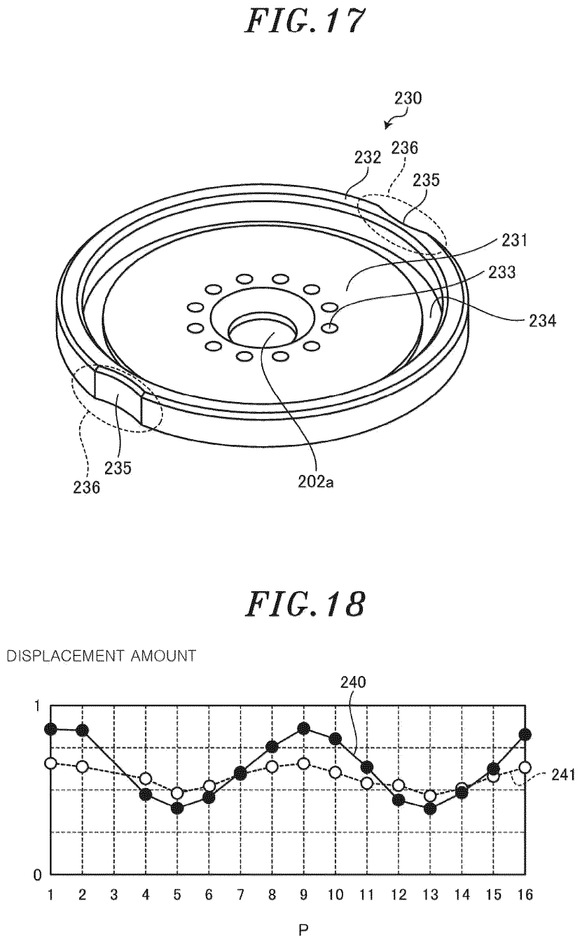

Next, Modification 4 will be described with reference to FIG. 17. FIG. 17 shows an example of a mounting pad according to Modification 4. A mounting pad 230 shown in FIG. 17 is modification in which the mounting pad 70 shown in FIG. 6 and the base 211 of the mounting pad 200 shown in FIG. 15 are combined. The mounting pad 230 also has a portion where the thickness of the outer edge portion in contact with the substrate W is not uniform in the circumferential direction of the outer edge portion. The mounting pad 230 has an annular outer edge portion 232 higher than the circular base 231. The mounting pad 230 has an opening 202a at the center of the base 231, and a plurality of through-holes 233 are disposed on the outer peripheral side of the opening 202a. The opening 202a is an example of a through-hole, similarly to the opening 202. The through-holes 233 respectively communicate with the suction holes V1b on the mounting mechanism EE31b side when the mounting pad 230 is attached to the pad mounting portion V13.

The mounting pad 230 has an annular groove 234 formed between the through-holes 233 of the base 231 and the outer edge portion 232. The groove 234 has a width smaller than that of the groove 214 of the mounting pad 200. The distance from the center of the base 231 to the inner circumferential side of the groove 234 is the same in the circumferential direction. In other words, the mounting pad 230 does not have portions corresponding to the protrusions 215 of the mounting pad 200.

The mounting pad 230 has one or more recesses 235 on the outer circumferential surface side of the outer edge portion 232. In other words, the recesses 235 are formed such that the outer circumference of the outer edge portion 232 becomes close to the center of the base 231 in at least one portion of the outer edge portion 232, and the distance between the outer circumference and the inner circumference of the outer edge portion 232 is smaller in the corresponding portion than that in the other portions of the outer edge portion 232. In the example of FIG. 17, two recesses 235 are arranged at intervals of 180° in the circumferential direction of the outer edge portion 232. In other words, the recesses 235 are formed at opposing positions on a straight line passing through the center of the mounting pad 230. In the mounting pad 230, the regions 236 where the two recesses 235 serve as the separation start points, so that the separation of the substrate W becomes easier.

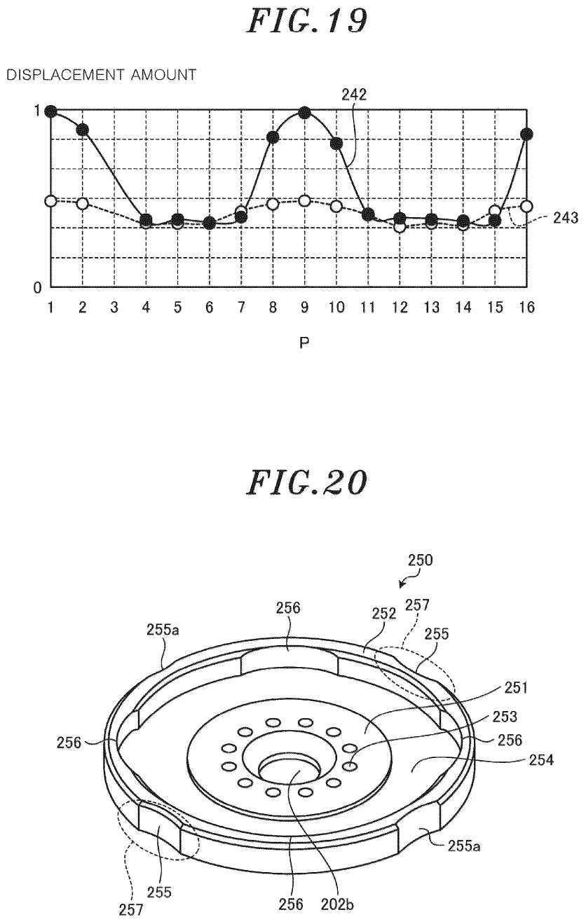

Next, the displacement amount comparison between the mounting pad 200 of the second embodiment and the mounting pad 230 of Modification 4 will be described with reference to FIGS. 18 and 19. In FIGS. 18 and 19, the displacement amount obtained when the substrate W is placed on the mounting pads 200 and 230 and pulled toward the positive side in the Z-axis direction (upper side in the vertical direction) with a force of 1[N].

FIG. 18 is a graph showing an example of the displacement amount in the Z-axis direction in the second embodiment and Modification 4. In FIG. 18, a graph 240 indicates the displacement amount of the mounting pad 200 in the Z-axis direction, and a graph 241 indicates the displacement amount of the mounting pad 230 in the Z-axis direction. In FIG. 18, the horizontal axis represents the positions P1 to P16 (corresponding to the positions P1 to P16 of FIG. 16) obtained by dividing the circumferential direction of the outer edge portions 212 and 232 into sixteen parts, and the vertical axis represents the normalize displacement amount within a range in which the displacement amount falls. The position P1 corresponds to the position P1 of FIG. 16 in the mounting pad 200, and corresponds to one of the recesses 235 in the mounting pad 230. The graph 240 shows that the displacement amount in the Z-axis direction increases at the positions P1 and P9, and decreases at the positions P5 and P13. The change in the displacement amount in the graph 241 is smaller than that in the graph 240. However, similarly to the graph 240, the graph 241 shows that the displacement amount in the Z-axis direction increases at the positions P1 and P9 and decreases at the positions P5 and P13.

FIG. 19 is a graph showing an example of the displacement amount in the radial direction in the second embodiment and Modification 4. In FIG. 18, a graph 242 shows the displacement amount of the mounting pad 200 in the radial direction (XY-axis direction), and a graph 243 shows the displacement amount of the mounting pad 230 in the radial direction (XY-axis direction). In FIG. 19, similarly to FIG. 18, the horizontal axis represents the positions P1 to P16, and the vertical axis represents the normalized displacement amount within a range in which the displacement amount falls. The graph 242 shows that the displacement amount in the radial direction increases at the positions P1 and P9 and decreases at the positions P4 to P7 and P11 to P15. The change in the displacement amount in the graph 243 is smaller than that in the graph 242. However, similarly to the graph 242, the graph 243 shows that the displacement amount in the radial direction increases at the positions P1 and P9 and decreases at the positions P4 to P6 and P12 to P14. From the comparison between the graph 242 and the graph 243, it is clear that the displacement amount in the radial direction is greatly affected by the protrusions 215 of the mounting pad 200. From the graph 243, it is clear that the displacement amount in the radial direction is greatly affected by the recesses 235 of the mounting pad 230. Further, in the graph 242, the inclination for the positions P1 to P4, P7 to P9, P9 to P11, and P15 to P16 is large. From the inclination, it is presumed that the positions P1 and P9 of the outer edge portion 212 of the mounting pad 200 serve as the separation start points.

Next, Modifications 5 to 7 will be described with reference to FIGS. 20 to 22. FIG. 20 shows an example of a mounting pad according to Modification 5. The mounting pad 250 shown in FIG. 20 is modification in which the protrusions 215 of the mounting pad 200 shown in FIG. 15 are omitted and the edge portions of the two recesses 216 facing the center of the mounting pad 200 with the protrusions 215 interposed therebetween are not chamfered. The mounting pad 250 also has a portion where the thickness of the outer edge portion in contact with the substrate W is not uniform in the circumferential direction of the outer edge portion. The mounting pad 250 has an annular outer edge portion 252 higher than a circular base 251. The mounting pad 250 has an opening 202b at the center of the base 251, and a plurality of through-holes 253 are disposed on the outer peripheral side of the opening 202b. The opening 202b is an example of a through-hole, similarly to the opening 202. The through-holes 253 respectively communicate with the suction holes V1b on the mounting mechanism EE31b side when the mounting pad 250 is attached to the pad mounting portion V13.

In the mounting pad 250, an annular groove 254 is formed between the through-holes 253 of the base 251 and the outer edge portion 252. The distance from the center of the base 251 to the inner circumference of the groove 254 is the same in the circumferential direction. In other words, the mounting pad 250 does not have portions corresponding to the protrusions 215 of the mounting pad 200.

The mounting pad 250 has one or more recesses among recesses 255 and recesses 255a on the outer circumferential surface side of the outer edge portion 252. In other words, one or more recesses among the recesses 255 and the recesses 255a are formed such that the outer circumference of the outer edge portion 252 becomes close to the center of the base 251 in at least one portion of the outer edge portion 252, and the distance between the outer circumference and the inner circumference of the outer edge portion 252 in the corresponding portion is smaller than that in the other portions of the outer edge portion 252. The recess 255a is different from the recess 255 in that the edge portion is not chamfered. The mounting pad 250 may have the recesses 255 instead of the recesses 255a. Further, the mounting pad 250 has one or more recesses 256 on the inner circumferential surface side of the outer edge portion 252. In other words, the recesses 256 are formed such that the inner circumference of the outer edge portion 252 becomes distant from the center of the base 251 in at least one portion of the outer edge portion 252, and the distance between the outer circumference and the inner circumference of the outer edge portion 252 in the corresponding portion is smaller than that in the other portions of the outer edge portion 252. In the example of FIG. 20, each of two recesses 255 and each of two recesses 255a (four in total) are alternately arranged at intervals of 90° in the circumferential direction of the outer edge portion 252. In addition, the four recesses 256 are arranged at intervals of 90° in the circumferential direction of the outer edge portion 252 while being shifted by 45° from the recesses 255 and 255a. In other words, the recesses 255 and 255a and the recesses 256 are alternately arranged along the circumferential direction of the outer edge portion 252. In the mounting pad 250, the regions 257 where the two recesses 255 exist serve as the separation start points, so that the separation of the substrate W becomes easier. The two recesses 255a may serve as the separation start points.

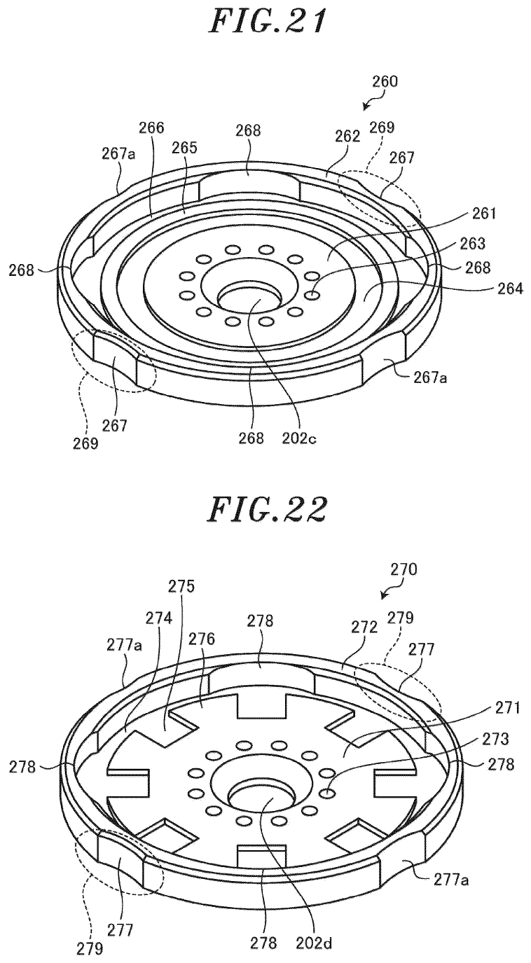

FIG. 21 shows an example of a mounting pad in Modification 6. A mounting pad 260 shown in FIG. 21 is modification in which the mounting pad 250 shown in FIG. 20 has dual grooves 254. The mounting pad 260 also has a portion where the thickness of the outer edge portion in contact with the substrate W is not uniform in the circumferential direction of the outer edge portion. The mounting pad 260 has an annular outer edge portion 262 higher than a circular base 261. The mounting pad 260 has an opening 202c at the center of the base 261, and a plurality of through-holes 263 are disposed on the outer peripheral side of the opening 202c. The opening 202c is an example of a through-hole, similarly to the opening 202. The through-holes 263 respectively communicate with the suction holes V1b on the mounting mechanism EE31b side when the mounting pad 260 is attached to the pad mounting portion V13.

The mounting pad 260 has annular grooves 264 and 266 formed between the through-hole 263 of the base 261 and the outer edge portion 262. An annular portion 265 of which thickness is the same as that of the portion of the base 260 close to the through-holes 263 is formed between the groove 264 and the groove 266. The distance from the center of the base 261 to the inner circumference of the groove 264 and the distance from the center of the base 261 to the outer circumference of the base 261 are the same in the circumferential direction. The distance from the center of the base 261 to the inner circumference of the groove 266 and the distance from the center of the base 261 to the outer circumference of the groove 266 are the same in the circumferential direction.

The mounting pad 260 has one or more recesses among recesses 267 and recesses 267a on the outer circumferential surface side of the outer edge portion 262. In other words, one or more recesses among the recesses 267 and the recesses 267a are formed such that the outer circumference of the outer edge portion 262 becomes close to the center of the base 261 in at least one portion of the outer edge portion 262, and the distance between the outer circumference and the inner circumference of the outer edge portion 262 in the corresponding portion is smaller than that in the other portions of the outer edge portion 262. The recess 267a is different from the recess 267a in that the edge portion is not chamfered. The mounting pad 260 may have the recesses 267 instead of the recesses 267a. Further, the mounting pad 260 may have one or more recesses 268 on the inner circumferential surface side of the outer edge portion 262. In other words, the recesses 268 are formed such that the inner circumference of the outer edge portion 262 becomes distant from the center of the base 261 in at least one portion of the outer edge portion 262, and the distance between the outer circumference and the inner circumference of the outer edge portion 262 in the corresponding portion is smaller than that in other portions of the outer edge portion 262. In the example of FIG. 21, each of two recesses 267 and each of two recesses 267a (four in total) are alternately arranged at intervals of 90° in the circumferential direction of the outer edge portion 262. Further, the four recesses 268 are arranged at intervals of 90° in the circumferential direction of the outer edge portion 262 while being shifted by 45° from the recesses 267 and 267a. In other words, the recesses 267 and 267a and the recesses 268 are alternately arranged along the circumferential direction of the outer edge portion 262. In the mounting pad 260, the regions 269 where the two recesses 267 exist serve as the separation start points, so that the separation of the substrate W becomes easier. The two recesses 267a may also serve as the separation start points.

FIG. 22 shows an example of a mounting pad according to Modification 7. The mounting pad 270 shown in FIG. 22 is modification in which the width of the groove 254 of the mounting pad 250 shown in FIG. 20 is reduced and a plurality of rectangular recesses having the same thickness as that of the groove 254 are formed from the groove 254 toward the center of the base 251 to provide a plurality of fan-shaped protrusions. The mounting pad 270 also has a portion where the thickness of the outer edge portion in contact with the substrate W is not uniform in the circumferential direction of the outer edge portion. The mounting pad 270 has an annular outer edge portion 272 higher than a circular base 271. The mounting pad 270 has an opening 202d at the center of the base 271, and a plurality of through-holes 273 are disposed on the outer peripheral side of the opening 202d. The opening 202d is an example of a through-hole, similarly to the opening 202. The through-holes 273 respectively communicates with the suction holes V1b on the mounting mechanism EE31b side when the mounting pad 270 is attached to the pad mounting portion V13.

The mounting pad 270 has an annular groove 274 between the through-holes 273 of the base 271 and the outer edge portion 272. In the groove 274, a plurality of rectangular recesses 275 having the same thickness as that of the groove 274 are formed from the groove 274 toward the center of the base 271, thereby forming a plurality of fan-shaped protrusions 276. The recesses 275 are arranged in eight directions obtained by dividing the circumferential direction of the base 271, for example. The protrusions 276 have the same thickness as that of the vicinity of the through-holes 273 of the base 271, and have a thickness different from that of the groove 274 in the circumferential direction of the groove 274. The protrusions 276 and the recesses 275 are alternately arranged. In other words, the thickness (width) of the groove 274 in at least one portion (where the protrusions 276 are disposed) of the groove 274 is different from that in the other portions of the groove 274.

The mounting pad 270 has one or more recesses among recesses 277 and recesses 277a on the outer circumferential surface side of the outer edge portion 272. In other words, one or more recesses among the recesses 277 and the recesses 277a are formed such that the outer circumference of the outer edge portion 272 becomes close to the center of the base 271 in at least one portion of the outer edge portion 272, and the distance between the outer circumference and the inner circumference of the outer edge portion 272 in the corresponding portion is smaller than that in the other portions of the outer edge portion 272. The recess 277a is different from the recess 277a in that the edge portion is not chamfered. The mounting pad 270 may have the recesses 277 instead of the recesses 277a. Further, the mounting pad 270 has one or more recesses 278 on the inner circumferential surface side of the outer edge portion 272. In other words, the recesses 278 are formed such that the inner circumference of the outer edge portion 272 becomes distant from the center of the base 271 in at least one portion of the outer edge portion 272, and the distance between the outer circumference and the inner circumference of the outer edge portion 272 in the corresponding portion in the corresponding portion is smaller than that in the other portions of the outer edge portion 272. In the example of FIG. 22, each of the two recesses 277 and each of the two recesses 277a (four in total) are alternately arranged at intervals of 90° in the circumferential direction of the outer edge portion 272. Further, the four recesses 278 are arranged at intervals of 90° in the circumferential direction of the outer edge portion 272 while being shifted by 45° from the recesses 277 and 277a. In other words, the recesses 277 and 277a and the recesses 278 are alternately arranged along the circumferential direction of the outer edge portion 272. In the mounting pad 270, the regions 279 where the two recesses 277 exist serve as the separation start points, so that the separation of the substrate W becomes easier. The two recesses 277a may also serve as the separation start points.

In the above-described embodiments, the mounting pads 10, 30, 40, 50, 60, 70, 100, 120, 200, 230, 250, 260, and 270 and the mounting mechanisms EE31, EE31a, and EE31b are separately provided. However, the present disclosure is not limited thereto. For example, the mounting pads 10, 30, 40, 50, 60, 70, 100, 120, 200, 230, 250, 260, and 270 may be integrally formed on one surfaces of the mounting mechanisms EE31, EE31a, and EE31b (to be an integrally molded product).

In accordance with the above-described embodiments, the mounting pad (for example, the mounting pads 10 and 200) for placing an object (substrate W) thereon comprises the base (for example, the bases 11 and 211) and the annular outer edge portion (for example, the outer edge portions 12 and 212) formed on one surface of the base. The outer edge portion projects in a direction intersecting the surface direction of the corresponding surface to surround an outer edge of the corresponding surface, and can be in contact with the object. The thickness of the outer edge portion in at least one portion (for example, the recesses 16 and 216) of the outer edge portion is different from a thickness of the outer edge portion in the other portions of the outer edge portion. As a result, the sticking of the object (substrate W) to the mounting mechanism EE31 or the like can be reduced.

Further, in accordance with the above-described embodiments, the mounting pad further comprises at least one through-hole (for example, the openings 13 and 202, the screw holes 14, and the through-holes 213) formed in the base. Accordingly, when the through-hole is the opening 13, for example, the substrate W can be attracted. When the through-hole is the screw hole 14, for example, the mounting pad 10 can be fixed to the mounting mechanism EE31. For example, the mounting pad 200 can be fixed to the mounting mechanism EE31b by the screw 201 in the opening 202, and the substrate W can be attracted by the suction hole V1a of the screw 201 and the suction holes V1b communicating with the through-holes 213.

Further, in accordance with the above-described embodiments, two or more portions where the outer edge portion has a different thickness are provided at rotationally symmetrical positions with the center of the base as the rotation axis. As a result, the sticking of the object to the mounting mechanism EE31 or the like can be reduced.

Further, in accordance with the above-described embodiments, the portions where the outer edge portion has a different thickness and the through-holes are disposed on a straight line. As a result, the sticking of the object to the mounting mechanism EE31 or the like can be further reduced.

Further, in accordance with the above-described embodiments, the portions (for example, the recesses 66, 76, and 235) where the outer edge portion (for example, the outer edge portions 62, 72, and 232) has different thicknesses are provided in two opposing positions. As a result, the mounting pads 60, 70, and 230 are easily deformed, and the sticking of the object to the mounting mechanism EE31 or the like can be further reduced.

Further, in accordance with the above-described embodiments, the through-holes include the first through-hole (for example, the opening 202) and the second through-holes (for example, the through-holes 213) having different diameters. As a result, the through-hole suitable for fastening and the through-hole suitable for suction can be formed.

Further, in accordance with the above-described embodiments, the first through-hole is disposed at the center of the base, two or more second through-holes are arranged around the first through-hole. The diameter of the through-hole is greater than the diameter of the second through-holes. As a result, the through-hole suitable for fastening and the through-hole suitable for suction can be formed.

Further, in accordance with the above-described embodiments, at least one portion (for example, the recesses 66, 76, and 216) of the outer edge portion (for example, the outer edge portions 62, 72, and 212) is disposed such that the outer circumference of the outer edge portion becomes close to the center of the base, and the distance between the outer circumference and the inner circumference of the outer edge portion in the corresponding portion is smaller than that in the other portions of the outer edge portion. As a result, the sticking of the object to the mounting mechanism EE31 or the like can be further reduced.

Further, in accordance with the above-described embodiments, at least one portion (for example, the recesses 16 and 217) of the outer edge portion is disposed such that the inner circumference of the outer edge portion becomes distant from the center of the base, and the distance between the outer circumference and the inner circumference of the outer edge portion in the corresponding portion is smaller than that in the other portions of the outer edge portion. As a result, the sticking of the object to the mounting mechanism EE31 or the like can be further reduced.

Further, in accordance with the above-described embodiments, the first portion that is at least one portion (for example, the recesses 216) of the outer edge portion (for example, the outer edge portion 212) is disposed such that the outer circumference of the outer edge portion becomes close to the center of the base, and the second portion that is at least one portion (for example, the recesses 217) of the outer edge portion is disposed such that the inner circumference of the outer edge portion becomes distant from the center of the base. The first portion and the second portion are alternately arranged along the circumferential direction of the outer edge portion. As a result, the displacement applied to the contact surface between the outer edge portion and the target is shifted, and the separation start points can be generated, which makes the separation of the target easier.

Further, in accordance with the above-described embodiments, the annular groove (for example, the grooves 78 and 214) is formed near the boundary between the base (for example, the bases 71 and 211) and the outer edge portion (for example, the outer edge portions 72 and 212). As a result, the mounting pad 70 and the like are more easily deformed, and the sticking of the object to the mounting mechanism EE31 and the like can be further reduced.

Further, in accordance with the above-described embodiments, the thickness of the groove in at least one portion of the groove (for example, portions of the groove 214 where the protrusions 215 are disposed) is different from that in the other portions of the groove. As a result, the displacement applied to the contact surface between the outer edge portion and the target can be shifted, and the separation start points can be generated, which makes the separation of the target easier.

Further, in accordance with the above-described embodiments, at least one portion (for example, the recesses 216) of the outer edge portion and at least one portion of the groove (for example, portions of the groove 214 where the protrusions 215 are disposed) are disposed on a straight line. As a result, the displacement applied to the contact surface between the outer edge portion and the target can be shifted, and the separation start points can be generated, which makes the separation of the target easier.

Further, in accordance with the above-described embodiments, the outer edge portion (the outer edge portions 42 and 52) has a circular or elliptical inner circumferential surface and a polygonal outer circumferential surface (the outer peripheral surfaces 45 and 55). As a result, the sticking of the object to the mounting mechanism EE31 or the like can be further reduced.

Further, in accordance with the above-described embodiments, the mounting mechanism (for example, the mounting mechanisms EE31 and EE31b) for placing an object thereon includes the exhaust passage (the suction passage V2) disposed in the mounting mechanism, and the mounting pad (for example, the mounting pads 10 and 200) disposed on one surface of the mounting mechanism. The mounting pad includes: the base (for example, the bases 11 and 211); at least one first through-hole (for example, the openings 13 and 202) disposed in the base and communicating with the exhaust passage; the through-holes 213 (the suction holes V1b); and the annular outer edge portion (for example, the outer edge portions 12 and 212) that is disposed on one surface of the base, projects in a direction intersecting the surface direction of the corresponding surface to surround the outer edge of the corresponding surface, and can be in contact with the object. The thickness of the outer edge portion in at least one portion (for example, the recesses 16 and 216) is different from that in the other portions of the outer edge portion. As a result, the sticking of the object (substrate W) to the mounting mechanism EE31 or the like can be reduced.

Further, in accordance with the above-described embodiments, the mounting mechanism is the support 110 on which the object can be attracted and held. As a result, the sticking of the object (substrate W) to the support 110 of the aligner AN can be reduced.

Further, in accordance with the above-described embodiments, the gap (for example, the gaps 125 and 205) exists between the outer edge portion and one surface of the mounting mechanism. As a result, the mounting pad 120 and the like are bent, and the outer edge portion can be brought into closer contact with the object (substrate W).

Further, in accordance with the above-described embodiments, the pad mounting portion (for example, the pad mounting portions V11 to V13) disposed on one surface of the mounting mechanism is further provided, and the mounting pad is mounted on the pad mounting portion. As a result, the mounting pad 10 and the like can be easily replaced.

Further, in accordance with the above-described embodiments, the mounting pad is integrally formed on one surface of the mounting mechanism. As a result, the configuration of the mounting mechanism can be simplified.

Further, in accordance with the above-described embodiments, the mounting mechanism is an end effector for transferring a substrate. As a result, the sticking of the substrate W to the end effector can be reduced.

Further, in accordance with the above-described embodiments, the mounting pad further includes at least one fastening hole (for example, the mounting holes 122, the opening 202) for a fastening member, which is formed in the base. As a result, the mounting pad 120 and the like can be mounted on the mounting mechanism EE31a and the like.

Further, in accordance with the above-described embodiments, the mounting pad (for example, the mounting pad 200) includes at least one fastening hole (for example, the opening 202) for a fastening member, which is formed in the base (for example, the base 211). The fastening member (for example, the screw 201) for fastening the mounting pad and the pad mounting portion (for example, the pad mounting portion V13) is fitted into the fastening hole. The fastening member has the second through-hole (for example, the suction hole V1a) formed along the fastening direction. As a result, the fastening hole and the suction hole can be shared.

Further, in accordance with the above-described embodiments, the seal member (for example, the O-rings 123 and 203) is disposed between the base and one surface of the mounting mechanism to surround all the first through-holes (for example, the openings 13 and 202, and the through-holes 213 (the suction holes V1b)) in plan view is further included. As a result, the close contact between the base and one surface of the mounting mechanism can be ensured. In addition, even if the mounting pad 200 or the like is bent more, the O-ring 203 suppresses the stress cracking of the mounting pad 200 or the like, so that the lifespan of the mounting pad 200 or the like can be increased.

Further, in accordance with the above-described embodiments, a part of the back surface of the base (for example, the base 11) and the pad mounting portion (for example, the pad mounting portion V11) are adhered. As a result, the area of the base 11 and the like can be reduced.

Further, in accordance with the above-described embodiments, the substrate transfer mechanism (for example, the atmospheric transfer robot TR3) for transferring the substrate W to the table (for example, the teeth 90) on which the substrate W is placed or receiving the substrate W from the table includes the mounting mechanism (for example, the mounting mechanisms EE31 and EE31b). In the mounting mechanism, the mounting pad (for example, the mounting pads 10 and 200) is disposed such that at least one of the thinnest portions of the outer edge portion (for example, the outer edge portions 12 and 212) faces a portion (for example, the region 90a) where the substrate W placed on the mounting mechanism can be in contact with the table. As a result, the sticking of the substrate W to the mounting mechanism can be further reduced.

Further, in accordance with the above-described embodiments, the substrate transfer mechanism (the atmospheric transfer robot TR3) includes the mounting mechanism EE31. In the mounting mechanism EE31, three or more mounting pads (for example, the mounting pads 10, 30, 60, 70, 100, and 200) are arranged at equal intervals from the center of the object, and at least two mounting pads are arranged such that the position (for example, the recesses 16, 66, 76, 106, and 216, and the regions 38 and 218) of the outer edge portion where the thickness of the outer edge portion in contact with the object is smallest faces the teeth 90. As a result, the separation start points 91 of the teeth 90 and the region (for example, the regions 17, 38, 67, 77, 107, and 218) serving as the separation start points of the mounting pad are close to each other, so that the sticking of the substrate W to the mounting mechanism EE31 can be further reduced.

Further, in accordance with the above-described embodiments, at least one mounting pad (for example, the mounting pads 10, 30, 60, 70, 100, and 200) is disposed such that the position (for example, the recesses 16, 66, 76, 106, and 216, and the regions 38 and 218) of the outer edge portion where the thickness of the outer edge portion in contact with the target is smallest is located on the straight line (the line 94) that connects the center of the object and the mounting pad. As a result, the center of the substrate W is aligned with the direction of the region (for example, the regions 17, 38, 67, 77, 107, and 218) serving as the separation start point of the mounting pad, and the sticking of the substrate W to the mounting mechanism EE31 can be further reduced.

Further, in accordance with the above-described embodiments, the outer edge portion 12 has an annular shape, and the outer edge portion 12 has a different thickness in one or more recesses (the recesses 16) disposed on the annular inner circumferential surface 15. As a result, the sticking of the substrate W to the mounting mechanism EE31 can be reduced.

Further, in accordance with the above-described embodiments, the outer edge portion (for example, the outer edge portions 62, 72, and 102) has an annular shape, and the outer edge portion has a different thickness in one or more recesses (for example, the recesses 66, 76, and 106) disposed on the annular outer circumferential surface (for example, the outer peripheral surfaces 65, 75, and 105). As a result, the mounting pads 60, 70, and 100 and the like are easily deformed, and the sticking of the substrate W to the mounting mechanism EE31 can be further reduced.

Further, in accordance with the above-described embodiments, the outer edge portion (for example, the outer edge portions 32, 42, and 52) have an annular shape, and the outer edge portion has a different thickness in one or more protrusions (for example, the protrusions 36, the corners 46 and 56) disposed on the annular outer circumferential surface (for example, the outer circumferential surface 35, 45, and 55). As a result, the sticking of the substrate W to the mounting mechanism EE31 can be reduced.

Further, in accordance with the above-described embodiments, three protrusions (for example, the protrusions 36) are arranged at equal intervals in the circumferential direction. As a result, the sticking of the substrate W to the mounting mechanism EE31 can be reduced.

Further, in accordance with the above-described embodiments, the protrusions (for example, the corners 46 and 56) includes corners. As a result, the sticking of the substrate W to the mounting mechanism EE31 can be further reduced.

Further, in accordance with the above-described embodiments, the outer edge portion (for example, the outer edge portions 42 and 52) has a circular or elliptical inner circumferential surface, and an outer circumferential surface (for example, the outer circumferential surfaces 45 and 55) formed as a flat surface with the corner (for example, the corners 46 and 56). As a result, the sticking of the substrate W to the mounting mechanism EE31 can be further reduced.

It should be noted that the embodiments of the present disclosure are illustrative in all respects and are not restrictive. The above-described embodiments may be omitted, replaced, or changed in various forms without departing from the scope of the appended claims and the gist thereof.

Further, in the above-described embodiments, the case where the outer edge portion 12 in contact with the substrate W has an annular shape of a single circle has been described. However, the present disclosure is not limited thereto. For example, the outer edge portion may have an annular shape of two or more concentric circles.

Further, in the above-described embodiments, the case where the substrate W is placed in the container C mounted on the load ports LP1 to LP4 has been described. However, the present disclosure is not limited thereto. For example, the substrate W may be placed on the support of the aligner AN, the stages of the load-lock modules LL1 and LL2, or the like. In that case, the center of the substrate W serves as the separation start point.

Further, in the above-described embodiments, the case where the object to be transferred is the substrate W has been described. However, the present disclosure is not limited thereto. For example, the object to be transferred may be a mounting mechanism capable of transferring a ring assembly accommodated in the storage SR or the like.

The present disclosure may employ the following configurations.
(1) A mounting pad for placing an object thereon, including:
a base; and
an annular outer edge portion that is disposed on one surface of the base, projects in a direction intersecting a surface direction of said one surface to surround an outer edge of said one surface, and is to be in contact with the object,
wherein a thickness of the outer edge portion in at least one portion of the outer edge portion is different from a thickness in the other portions of the outer edge portion.
(2) The mounting pad of (1), further including:
at least one through-hole formed in the base.
(3) The mounting pad of (1) or (2), wherein two or more portions where the outer edge portion has a different thickness are provided at rotationally symmetrical positions with a center of the base as a rotation axis.
(4) The mounting pad of (2), wherein the portions where the outer edge portion has a different thickness and the through-hole are located on a straight line.
(5) The mounting pad of any one of (1) to (4), wherein the portions where the outer edge portion has s different thickness are provided in two opposing positions.
(6) The mounting pad of any one of (1) to (5), wherein an annular groove is formed near a boundary between the base and the outer edge portion.
(7) The mounting pad of any one of (1) to (6), wherein the outer edge portion has a circular or elliptical inner circumferential surface and a polygonal outer circumferential surface.
(8) A mounting mechanism for placing an object, including:
an exhaust passage disposed in the mounting mechanism;
a mounting pad portion disposed on one surface of the mounting mechanism; and
a mounting pad mounted on the pad mounting portion,
wherein the mounting pad includes:
a base;
one or more through-holes disposed in the base and communicating with the exhaust passage; and
an annular outer edge portion that is disposed on one surface of the base, projects in a direction intersecting a surface direction of said one surface to surround an outer edge of said one surface, and is to be in contact with the object,
wherein a thickness of the outer edge portion in at least one portion of the outer edge portion is different from a thickness in the other portions of the outer edge portion.
(9) The mounting mechanism of (8), wherein the mounting mechanism is a support on which the object is attracted and held.
(10) The mounting mechanism of (8) or (9), wherein a gap exits between the outer edge portion and the pad mounting portion.
(11) The mounting mechanism of any one of (8) to (10), wherein at least one of the through-holes is a fastening hole for a fastening member, and
a seal member is disposed between the base and the pad mounting portion to surround all the through-holes.
(12) The mounting mechanism of any one of (8) to (10), wherein a part of the back surface of the base and the pad mounting portion are adhered.
(13) A substrate transfer mechanism including the mounting mechanism described in any one of (8) to (12), wherein three or more mounting pads are arranged at equal intervals from the center of the object, and at least two mounting pads are arranged such that the position of the outer edge portion where the thickness of the outer edge portion in contact with the object is smallest faces the teeth.
(14) The substrate transfer mechanism of (13), wherein at least one mounting pad is disposed such that a position of the outer edge portion where the thickness of the outer edge portion in contact with the target is smallest is located on the straight line that connects the center of the object and the mounting pad.

The present disclosure may also employ the following configurations.
(1) A mounting pad for placing an object, comprising:
a base; and
an annular outer edge portion that is provided on one surface of the base, projects in a direction intersecting a surface direction of said one surface to surround an outer edge of said one surface, and is to be in contact with the object,
wherein a thickness of the outer edge portion in at least one portion of the outer edge portion is different from a thickness of the outer edge portion in other portions of the outer edge portion.
(2) The mounting pad of (1), further comprising at least one through-hole formed in the base.
(3) The mounting pad of (1) or (2), wherein said at least one portion of the outer edge portion having the different thickness are provided at two or more positions that are rotationally symmetrical with a center of the base as a rotation axis.
(4) The mounting pad of (2), wherein said at least one through-hole includes a first through-hole and a second through-hole having different diameters.
(5) The mounting pad of (4), wherein the first through-hole is disposed at a center of the base,
two or more of the second through-holes are disposed around the first through-hole, and
a diameter of the first through-hole is greater than a diameter of the second through-holes.
(6) The mounting pad of any one of (1) to (5), wherein said at least one portion of the outer edge portion is provided such that an outer circumference of the outer edge portion becomes close to a center of the base, and
a distance between the outer circumference and an inner circumference of the outer edge portion in said at least one portion where the outer circumference of the outer edge portion becomes close to the center of the base is smaller than a distance between an outer circumference and an inner circumference of the outer edge portion in the other portions of the outer edge portion.
(7) The mounting pad of any one of (1) to (6), wherein said at least one portion of the outer edge portion is provided such that an inner circumference of the outer edge portion becomes distant from a center of the base, and
a distance between an outer circumference and the inner circumference of the outer edge portion in said at least one portion where the inner circumference of the outer edge portion becomes distant from the center of the base is smaller than a distance between an outer circumference and an inner circumference of the outer edge portion in the other portions of the outer edge portion.
(8) The mounting pad of any one of (1) to (7), wherein a first portion among said at least one portion of the outer edge portion is provided such that an outer circumference of the outer edge portion becomes close to the center of the base,
a second portion among said at least one portion of the outer edge portion is provided such that an inner circumference of the outer edge portion becomes distant from the center of the base, and
the first portion and the second portion are alternately arranged along a circumferential direction of the outer edge portion.
(9) The mounting pad of any one of (1) to (8), wherein the base includes an annular groove formed near a boundary between the base and the outer edge portion.
(10) The mounting pad of (9), wherein a thickness of the groove in at least one portion of the groove is different from a thickness of the groove in other portions of the groove.
(11) The mounting pad of (10), wherein said at least one portion of the outer edge portion and said at least one portion of the groove are disposed on a straight line.
(12) A mounting mechanism for placing an object, comprising:
an exhaust passage provided in the mounting mechanism; and
a mounting pad disposed on one surface of the mounting mechanism,
wherein the mounting pad includes:
a base;
at least one first through-hole provided in the base and communicating with the exhaust passage; and
an annular outer edge portion that is disposed on one surface of the base, projects in a direction intersecting a surface direction of said one surface to surround an outer edge of said one surface, and is to be in contact with the object,
wherein a thickness of the outer edge portion in at least one portion of the outer edge portion is different from a thickness of the outer edge portion in other portions of the outer edge portion.
(13) The mounting pad of (12), wherein a gap exists between the outer edge portion and said one surface of the mounting mechanism.
(14) The mounting pad of (12) or (13), further comprising:
a pad mounting portion disposed on said one surface of the mounting mechanism, and
the mounting pad is mounted on the pad mounting portion.
(15) The mounting pad of (12) or (13), wherein the mounting pad is integrally formed on said one surface of the mounting mechanism.
(16) The mounting mechanism of any one of (12) to (15), wherein the mounting mechanism is an end effector for transferring a substrate.
(17) The mounting mechanism of any one of (12) to (14), wherein the mounting pad further includes at least one fastening hole for a fastening member, which is formed in the base.
(18) The mounting mechanism of (14), wherein the mounting pad further includes at least one fastening hole for a fastening member, which is formed in the base,
a fastening member for fastening the mounting pad and the pad mounting portion is fitted into said at least one fastening hole, and
the fastening member has a second through-hole formed along a fastening direction.
(19) The mounting mechanism of any one of (12) to (14), further comprising:
a seal member disposed between the base and said one surface of the mounting mechanism to surround all the first through-holes in plan view.
(20) A substrate transfer mechanism for transferring a substrate to a table for placing the substrate or receiving the substrate from the table, comprising:
the mounting mechanism described in (12),
wherein in the mounting mechanism, the mounting pad is provided such that at least one of thinnest portions of the outer edge portion faces a portion where the substrate placed on the mounting mechanism is to be in contact with the table.

1. A mounting pad for placing an object, comprising:
a base; and
an annular outer edge portion that is provided on one surface of the base, projects in a direction intersecting a surface direction of said one surface to surround an outer edge of said one surface, and is to be in contact with the object,
wherein a thickness of the outer edge portion in at least one portion of the outer edge portion is different from a thickness of the outer edge portion in other portions of the outer edge portion.

2. The mounting pad of claim 1, further comprising at least one through-hole formed in the base.

3. The mounting pad of to claim 1, wherein said at least one portion of the outer edge portion having the different thickness are provided at two or more positions that are rotationally symmetrical with a center of the base as a rotation axis.

4. The mounting pad of claim 2, wherein said at least one through-hole includes a first through-hole and a second through-hole having different diameters.

5. The mounting pad of claim 4, wherein the first through-hole is disposed at a center of the base,
two or more of the second through-holes are disposed around the first through-hole, and
a diameter of the first through-hole is greater than a diameter of the second through-holes.

6. The mounting pad of claim 1, wherein said at least one portion of the outer edge portion is provided such that an outer circumference of the outer edge portion becomes close to a center of the base, and
a distance between the outer circumference and an inner circumference of the outer edge portion in said at least one portion where the outer circumference of the outer edge portion becomes close to the center of the base is smaller than a distance between an outer circumference and an inner circumference of the outer edge portion in the other portions of the outer edge portion.

7. The mounting pad of claim 1, wherein said at least one portion of the outer edge portion is provided such that an inner circumference of the outer edge portion becomes distant from a center of the base, and
a distance between an outer circumference and the inner circumference of the outer edge portion in said at least one portion where the inner circumference of the outer edge portion becomes distant from the center of the base is smaller than a distance between an outer circumference and an inner circumference of the outer edge portion in the other portions of the outer edge portion.

8. The mounting pad of claim 1, wherein a first portion among said at least one portion of the outer edge portion is provided such that an outer circumference of the outer edge portion becomes close to the center of the base,
a second portion among said at least one portion of the outer edge portion is provided such that an inner circumference of the outer edge portion becomes distant from the center of the base, and
the first portion and the second portion are alternately arranged along a circumferential direction of the outer edge portion.

9. The mounting pad of claim 1, wherein the base includes an annular groove formed near a boundary between the base and the outer edge portion.

10. The mounting pad of claim 9, wherein a thickness of the groove in at least one portion of the groove is different from a thickness of the groove in other portions of the groove.

11. The mounting pad of claim 10, wherein said at least one portion of the outer edge portion and said at least one portion of the groove are disposed on a straight line.

12. A mounting mechanism for placing an object, comprising:
an exhaust passage provided in the mounting mechanism; and
a mounting pad disposed on one surface of the mounting mechanism,
wherein the mounting pad includes:
a base;
at least one first through-hole provided in the base and communicating with the exhaust passage; and
an annular outer edge portion that is disposed on one surface of the base, projects in a direction intersecting a surface direction of said one surface to surround an outer edge of said one surface, and is to be in contact with the object,
wherein a thickness of the outer edge portion in at least one portion of the outer edge portion is different from a thickness of the outer edge portion in other portions of the outer edge portion.

13. The mounting pad of claim 12, wherein a gap exists between the outer edge portion and said one surface of the mounting mechanism.

14. The mounting pad of claim 12, further comprising:
a pad mounting portion disposed on said one surface of the mounting mechanism, and
the mounting pad is mounted on the pad mounting portion.

15. The mounting pad of claim 12, wherein the mounting pad is integrally formed on said one surface of the mounting mechanism.

16. The mounting mechanism of claim 12, wherein the mounting mechanism is an end effector for transferring a substrate.

17. The mounting mechanism of claim 12, wherein the mounting pad further includes at least one fastening hole for a fastening member, which is formed in the base.

18. The mounting mechanism of claim 14, wherein the mounting pad further includes at least one fastening hole for a fastening member, which is formed in the base,
a fastening member for fastening the mounting pad and the pad mounting portion is fitted into said at least one fastening hole, and
the fastening member has a second through-hole formed along a fastening direction.

19. The mounting mechanism of claim 12, further comprising:
a seal member disposed between the base and said one surface of the mounting mechanism to surround all the first through-holes in plan view.

20. A substrate transfer mechanism for transferring a substrate to a table for placing the substrate or receiving the substrate from the table, comprising:
the mounting mechanism described in claim 12,
wherein in the mounting mechanism, the mounting pad is provided such that at least one of thinnest portions of the outer edge portion faces a portion where the substrate placed on the mounting mechanism is to be in contact with the table.
